(19) United States
(12) Patent Application Publication
(10) Pub. No.: US 2014/0168929 A1
(43) Pub. Date: Jun. 19, 2014

(54) DISPLAY APPARATUS

(71) Applicant: Paul Terry, Wolverhampton (GB)

(72) Inventor: Paul Terry, Wolverhampton (GB)

(73) Assignee: DP MEMORABILIA LIMITED, Wolverhampton (GB)

(21) Appl. No.: 14/237,081

(22) PCT Filed: Aug. 3, 2012
(86) PCT No.: PCT/GB2012/000635

§ 371 Date: Feb. 4, 2014

(30) Foreign Application Priority Data
Aug. 5, 2011 (GB) 1113551.4

(51) Int. Cl. H05K 7/14; H05K 13/00

(52) U.S. Cl. CPC H05K 7/14; H05K 13/00
USPC 361/809; 29/592.1

(57) ABSTRACT

A display apparatus comprising a picture frame containing a space for an article to be displayed, an electronic image display unit, and at least one of (a) a control unit for controlling the image display unit, and (b) a battery unit for powering the image display unit. The image display unit is separately mounted in the picture frame from the control unit and/or battery unit(s) and is connected thereto by at least one cable. All other things being equal, by decoupling the image display unit from its control unit(s) and/or battery unit(s), each unit can be of a smaller size so that there is a greater choice as to the location of each unit. Furthermore, the image display unit, for example, can be positioned offcentre in the frame, and yet the other unit(s) can be positioned so that the centre of gravity of the whole apparatus lies on the vertical centre-line of the frame, so that the frame can be suspended from a single central point and will hang straight.

This invention relates to improvements in or relating to display apparatus and is more particularly concerned with a display apparatus comprising a display case or picture frame having a space or opening for an article to be displayed.

Such an apparatus is, or course, very well known and may form the basis of a conventional framed photograph or painting or the like which may e.g. be arranged in a standing position on a horizontal support surface such as a table top, or hung on a wall or other vertical support.

It is known to frame or display a sports shirt in this way and to hang the framed shirt on a wall. Framed football shirts are popular among football fans, especially if, for example, the shirt is the team shirt of a club supported by the fan and in particular if the shirt bears the number and/or name (even the signature) of their favourite player in the club. Such framed football shirts can be particularly valuable if, for example, they bear the original signature of a famous player and/or have actually been worn by that player in a match.

The present invention was originally conceived as a way of providing further interest to framed football shirts. However, importantly, it is also applicable to the display of other articles or information, such as memorabilia or paraphernalia related e.g. to celebrities, the world of film or TV, or history. To this end, the display apparatus of embodiments of the present invention may also include or contain an electronic or powered audio and/or image/media display (e.g. LCD) or the like usually theme related to the article being displayed. Therefore, in addition to displaying, for example, a team shirt of a favourite football player, the apparatus could also display, for example, a slideshow of still pictures/images or a recorded video of that football player in action.

Such a display apparatus has already been proposed in Patent Specification No. W02008/138933A 1. In that apparatus, a multimedia player 3 is provided as part of content delivery means 2 having an LCD screen 4 in the apparatus below a cavity in the frame for holding an item of memorabilia or merchandise such as a football shirt. The content delivery means 2 may be an integrated unit or arrangement including the multimedia player 3 and having the LCD screen 4, speakers, controls, a battery, an input for connection to an external power supply, memory, a USB port, a WIFI or Bluetooth interface and a reader for a removable storage medium. As shown in the FIGURES of the drawings in W02008/138933A1, the content delivery means with multimedia player occupies a substantially greater space/area than the space/area provided for holding the item of memorabilia, and the LCD screen of the content delivery means occupies only a relatively small part of the area occupied by the content delivery means. The volume occupied by the content delivery means of W02008/138933A1 is substantial, and, as shown in the drawings of W02008/138933A1, the item of memorabilia and LCD screen lie on the vertical centre line of the picture frame. Even so, there is no disclosure of relative weight distribution of the various components of the display apparatus and the control panel 6 of the multimedia player is offset from the centre line suggesting a possible inbalance in weight distribution. Thus, disadvantageously, the display apparatus might not necessarily hang straight vertically in a balanced manner if suspended from an upper central point location. Additionally, it tends to be disadvantageous that the size of content delivery means including all the various components (in particular control panel and battery) in relation to the size of the display apparatus would appear to be unnecessarily restrictive on the possible locations of the LCD screen and control panel relative to the cavity for holding an item of memorabilia, more particularly if the display apparatus is or were to be balanced (or approximately balanced) about the centre line.

An object of the present invention is to at least alleviate one of the aforementioned, or other, disadvantages associated with display apparatus having an opening or space for displaying an article and an electronic or powered audio and/or image/media display or the like, or to provide such a display apparatus which is improved in at least some respect, or at least in specific embodiments, to provide a display apparatus which may provide a greater flexibility in choosing or selecting the relative locations of image display screen and opening/space for an article to be displayed.

According to a first aspect of the present invention there is provided a display apparatus comprising: a display case or picture frame having or containing an opening/space for an article to be displayed; an electronic or powered image display unit, and at least one of:—
a) at least one control unit for controlling the image display unit and
b) at least one battery unit or power source for powering the image display unit,
   said image display unit being separately mounted from the at least one control unit and/or the at least one battery unit or power source in the case/picture frame and connected or connectable thereto by at least one operative connection or cable.

Advantageously, according to this aspect of the present invention, by separating or physically decoupling the image display unit from its control unit(s) and/or power source(s) or battery unit(s), the image display unit can be of a smaller size than might otherwise be the case i.e. of smaller size than a combined integrated unit, in order to provide a greater choice or selection as to the location of each unit within the display apparatus.

Additionally, and very advantageously, where a power source(s) or battery unit(s) is/are Separately mounted as aforesaid it may be possible to provide a battery/energy life of up to 16 hours or more e.g. even 170 hours or so rather e.g. 2 hours (especially where more than one battery unit is provided) as might be available in prior art arrangements, thereby very significantly reducing time between charging the battery unit(s) and possibly reducing the overall weight of the apparatus. Additionally, separating or physically decoupling the image display unit from the power source(s) enables utilization of lower power screen technologies currently in development or not economically available (such as OLED and Reflective Video (RV)), thereby providing a longer energy life time using the same power source(s). To summarise, separating the image display unit from its power source(s)/battery unit(s) allows a greater physical size (s) and power of the power source(s)/battery (units) to be provided.

Whilst it is possible for the image display in some designs of display apparatus to be powered from the mains via a cable connection the Applicant believes in many cases this tends to be inconvenient and unsightly. Thus, the Applicant is mainly concerned with display apparatus that can be used for a reasonable length of time continuously (e.g. 16 hours or so) under its own power source (s) located in the display apparatus itself. An additional mains power connection could be provided.

Furthermore, the image display unit, for example, may be designed to be positioned asymmetrically or off-centre in the frame (or off the centre-line), with the other aforementioned unit(s) selectively positioned so that the centre of gravity of the whole apparatus lies on the vertical centre-line of the frame, and so that the frame can be suspended from a single central point and hang vertically in a straight, balanced manner. The principle of moments could be utilized to ascertain or preselect the required positions of all said units in order to sufficiently accurately place the centre of gravity.

The display case or picture frame may have framing members at the edges thereof, and the at least one control unit is, preferably, disposed adjacent one of the framing members and is, preferably, accessible through an aperture in or through that framing member. The accessible part of said control unit may be, therefore, unobtrusive. Said one framing member is, preferably, disposed on the right or the left of the picture frame, so that in most circumstances said control unit can be readily seen/operated by a user at one side of the frame. By contrast, in the arrangement of Patent Specification No. WO2008/138933A1, the user-accessible control panel is exposed in the underside of the lower framing member.

Said control unit, preferably, includes means for receiving and/or storing a video or picture file and/or video stream and for generating a video monitor signal therefrom. The image display unit is, preferably, simply a monitor connected to receive the video monitor signal from the control unit and operable to display a still and/or moving picture represented by the video monitor signal. The size of the image display unit and in particular its thickness can therefore be relatively small and unobtrusive.

The display apparatus may include means for mounting the or each battery unit, or at least one of the battery units, in a range of (preferably lateral) positions across the picture frame and securing it in a selected one of said positions. The battery unit(s) can therefore be used to balance the display apparatus as a whole.

The picture frame, preferably, contains a transparent front panel covering the opening/space for the article to be displayed, and also covering the image display unit and the control unit(s) and/or battery unit(s).

Also, the picture frame, preferably, contains an opaque panel/section which covers the control unit(s) and/or battery unit(s) and which has an aperture revealing the image display unit. Advantageously, this panel/section assists in providing a clean and neat appearance to the display apparatus. The opening/space for the article to be displayed may be provided between the transparent panel and the opaque pane/section. Alternatively, the frame may contain a second opaque panel mounted behind a second aperture in the first-mentioned opaque panel, in which case the opening/space for the article to be displayed may be provided in and/or behind the second aperture in the first opaque panel and in front of the second opaque panel. Such facility also assists in providing a clean and neat appearance to the display apparatus and enables the first opaque panel to lie flat against the inner face of the transparent panel without bowing, despite the displayed article possibly having a substantial thickness, especially if a spacer member is provided in between the first and second opaque panels.

In a preferred embodiment, a shaped panel member or spacer means is disposed within the frame behind the image display unit and the control unit(s) and/or battery unit(s) and is shaped to engage the frame, the image display unit and the control unit(s) and/or battery unit(s) so as to maintain their relative positions. The shaped panel member may be of vacuum-formed plastics material. Even so another advantage of separating or physically decoupling the power source(s)/battery unit(s) and/or the at least one control unit from the image display unit is that it substantially reduces the size, thickness and weight of the image display so that a vacuum form to support and position the image display unit need no longer be required (thereby reducing costs and complexity). Instead, the image display may simply be fixed to the reverse side of a mounting card/plate (preferably using a locating jig).

The display apparatus may further include means to enable the display case picture frame to be hung from or engage a picture hook or other mount on a wall or vertical surface.

In accordance with other aspects of the present invention, there are provided methods of manufacture of a display apparatus having at least some of the features as related above, so that the completed apparatus is selectively balanced.

In particular; according to a second aspect of the present invention there is provided a method of making a display apparatus including the steps of selecting a picture frame; image display unit; at least one control unit and at least one battery unit; choosing or selecting positions for the image display unit, the or each control unit and the or each battery unit in the picture frame, so that, when in those positions, the overall centre of gravity of the display apparatus lies substantially on a vertical centre-line of the picture frame; and, possibly, vacuum-forming a sheet of plastics material to fit the image display unit, the control unit and the or each battery unit in the chosen positions in the picture frame or, preferably, fixing the image display to a mounting card/plate.

The sheet of plastics material may be vacuum-formed using the picture frame, image display unit, control unit and the or each battery unit as formers in the vacuum-forming process but, as previously stated, the image display may simply be fixed to a mounting card/plate.

According to a third aspect of the present invention there is provided a method of making a display apparatus including the steps of: selecting a picture frame, image display unit, at least one control unit and at least one battery unit; choosing or selecting positions for the image display unit and the or each control unit in the picture frame: calculating a position for the or each battery unit so that, when in that position, the overall centre of gravity of the display apparatus lies substantially on a vertical centre-line of the picture frame; and assembling the display apparatus in accordance with the chosen and calculated positions.

According to a fourth aspect of the present invention there is provided a method of making a display apparatus including the steps of: selecting a picture frame, image display unit, at least one control unit and at least one battery unit; assembling the picture frame, image display unit, the or each control unit and the or each battery unit; adjusting the lateral position of said at least one battery unit so that the overall centre of gravity of the display apparatus lies substantially on a vertical centre-line of the picture frame: and securing said at least one battery unit in the adjusted position.

The display apparatus may have a case or picture frame of any selected size or shape which could be rectangular, square, circular, elliptical, or polygonal but is preferably of symmetrical shape in order to more easily arrange for the centre of gravity to lie on a centre line of the display case/picture frame.

Even so, it possible, in some embodiments of the present invention, that the case/frame is asymmetric and/or it may be arranged for the weight distribution of units in the display apparatus be deliberately designed for the apparatus to have a centre of gravity that may be offset, for the apparatus to be capable of being hung in a chosen orientation to the vertical (i.e. not necessarily straight).

In such a design it is important that the case/frame can be hung in a selected orientation suited for displaying said article in relation to the image display unit.

Therefore further according to the present invention there is provided a display apparatus having one or more of the following features:—

a) A first area or region adapted for the display of an article of memorabilia or the like and at least one powered media (preferably image) display, said apparatus having a power source e.g. a battery separately mounted or mountable in the apparatus in a second selected region/area of the apparatus
b) A first area or region adapted for the display of an article of memorabilia or the like and at least one powered media (preferably image) display, said apparatus having a control unit for the powered media display separately mounted or mountable in the apparatus in a second selected region/area of the apparatus
c) A display apparatus according to a) or b) above in which the power source and/or control unit are positioned in the apparatus to selectively place the centre of gravity of the apparatus (usually on the centre line of the apparatus) in order that the apparatus can by hung from a point location in a particular chosen orientation (usually straight and symmetrical), said positions of the power source and/or control unit, preferably, being variable or adjustable to suit the desired orientation.

It is possible that the image display is connectable to an external power source since as a mains supply, preferably, via a port in the display case/frame or e.g. via a port in the control unit.

More generally, according to the present invention, there is provided a method of making a display apparatus comprising the steps of:—

selecting a picture frame or display case and or image display unit; selecting at least one of; at least one control unit for controlling the image display unit and at least one power source or battery unit; choosing a position for the image display unit, choosing and/or calculating positions for the or each control unit/power source or battery unit in the picture frame/display case, so that, when in these positions, the overall centre of gravity of the display apparatus lies substantially on a vertical centerline of the picture frame/display apparatus or at a pre-selected location, and assembling the display apparatus in accordance with the chosen/calculated positions of the or each control unit/power source or battery unit.

Further according to the present invention there is provided a method of making a display apparatus comprising the steps of:—

selecting a picture frame or display case and an image display unit; selecting at least one of; at least one control unit for controlling the image display unit and at least one power source or battery unit; choosing a position for the image display unit, mounting the image display unit in the picture frame/display case separately to the at least one control unit and/or power source/battery unit(s) and operatively connecting the image display unit to the control unit(s) and/or power source or battery unit(s) and, preferably, choosing and/or calculating positions for the or each control unit/power source or battery unit in the picture frame/display case, so that, when in these positions, the overall centre of gravity of the display apparatus lies substantially on a vertical centerline of the picture frame/display apparatus or at a pre-selected location, and assembling the display apparatus in accordance with the chosen/calculated positions of the or each control unit/power source or battery unit.

An embodiment of a display apparatus in accordance with the present invention will now be described, by way of example only, with reference to the accompanying drawings, in which:

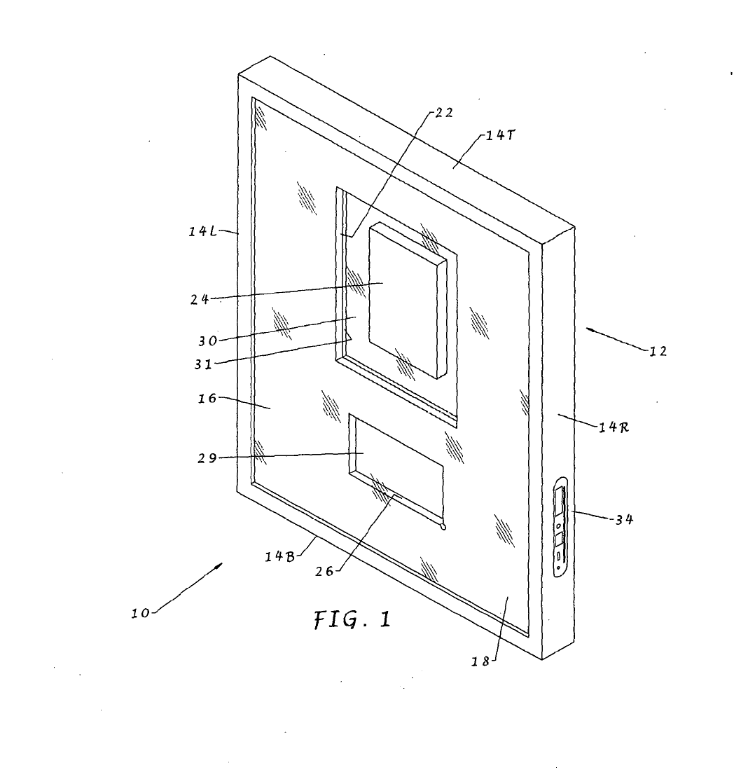

FIG. 1 is a front isometric view of the display apparatus;

FIG. 2 is a rear isometric view of a frame of the apparatus;

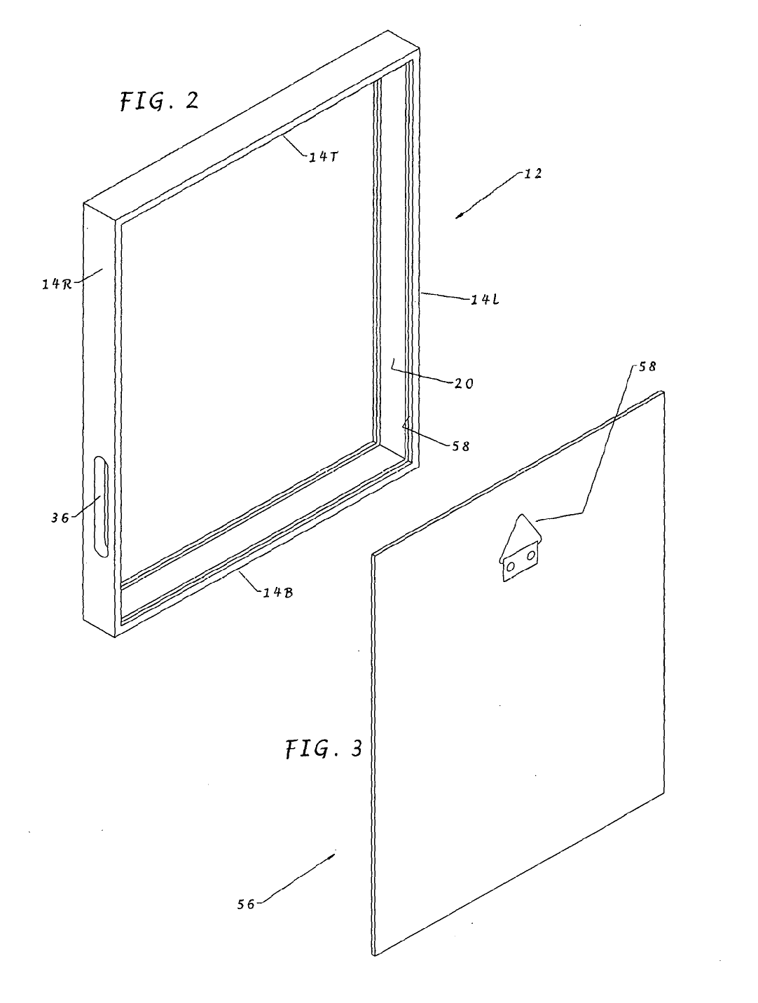

FIG. 3 is a rear isometric view of a backing board of the apparatus;

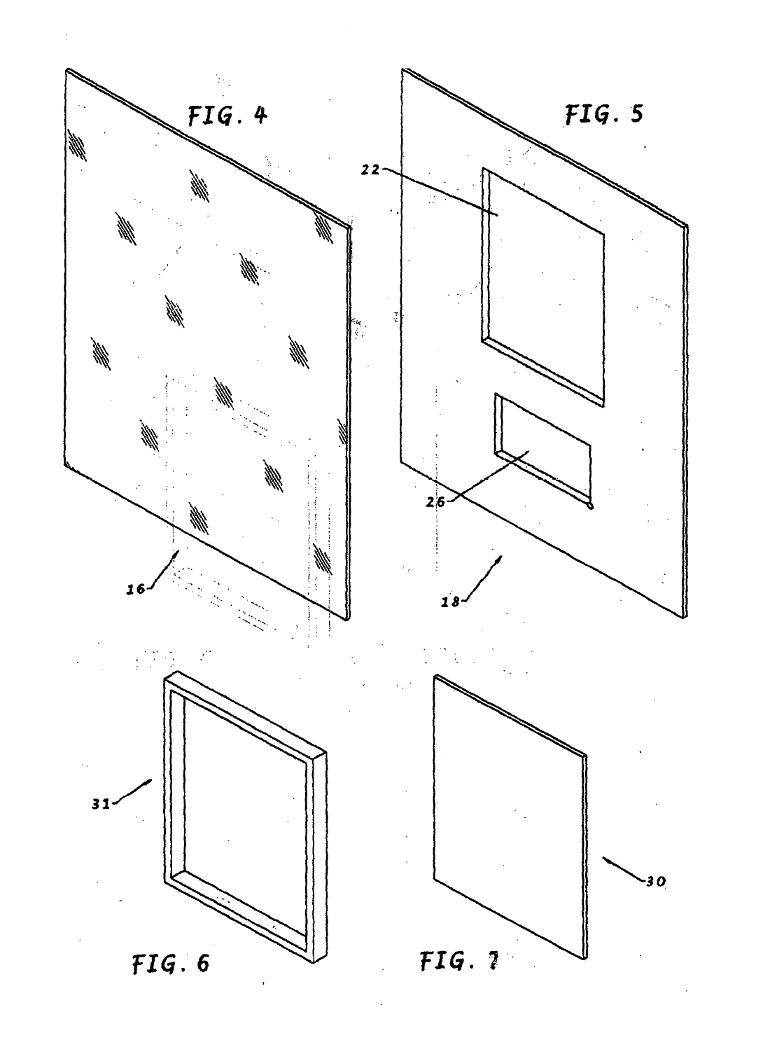

FIG. 4 is an isometric view of a glass for the apparatus;

FIG. 5 is a front isometric view of a first inner panel for the apparatus;

FIG. 6 is an isometric view of a spacer for the apparatus;

FIG. 7 is an isometric view of a second inner panel for the apparatus;

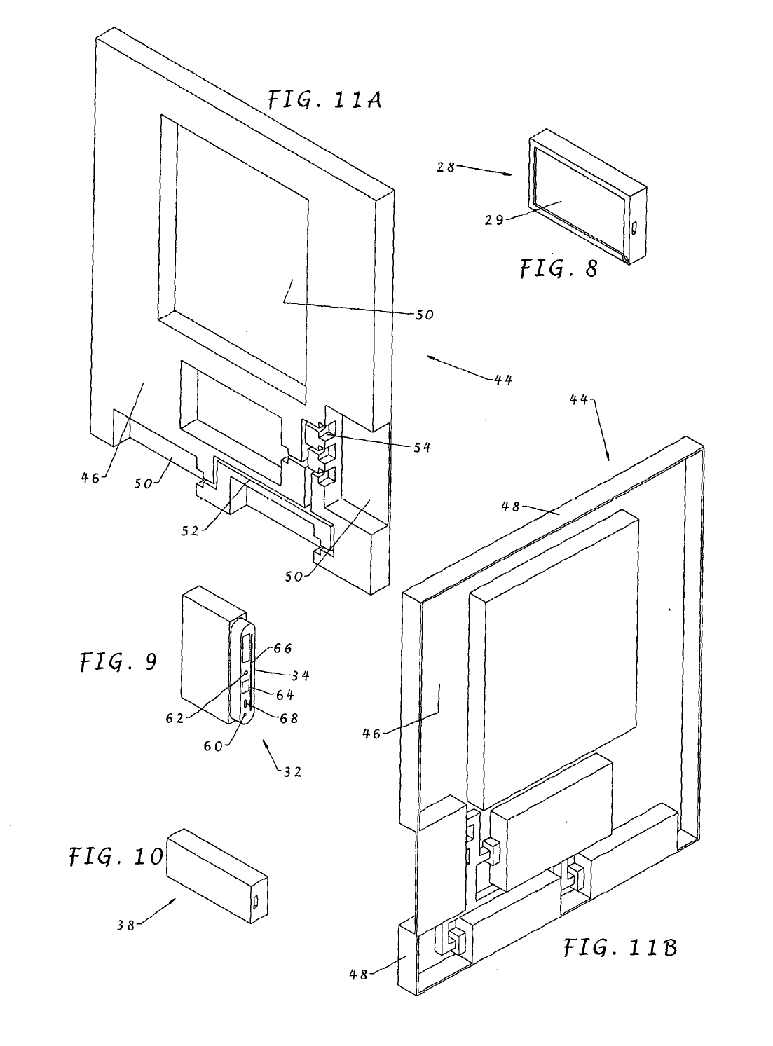

FIG. 8 is a front isometric view of an electronic display unit for the apparatus;

FIG. 9 is a front isometric view of a control unit for the apparatus;

FIG. 10 is a front isometric view of a battery for the apparatus;

FIGS. 11A & 11B are front and rear isometric views, respectively, of a vacuum-formed tray of the apparatus;

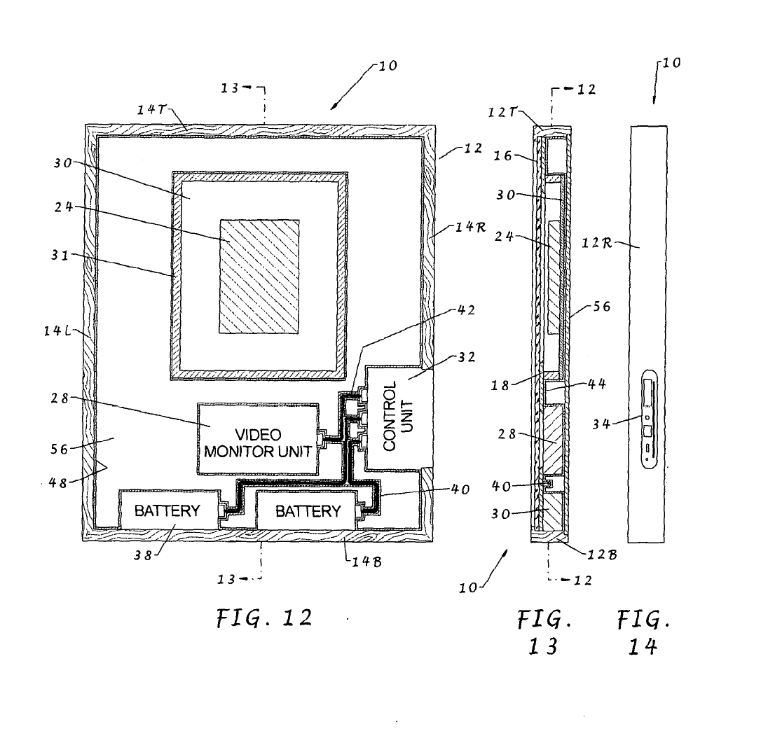

FIG. 12 is a sectioned front view of the apparatus, taken on the section line 12-12 shown in FIG. 13;

FIG. 13 is a sectioned side view of the apparatus, taken on the section line 13-13 shown in

FIG. 12;

FIG. 14 is a side view of the apparatus; and

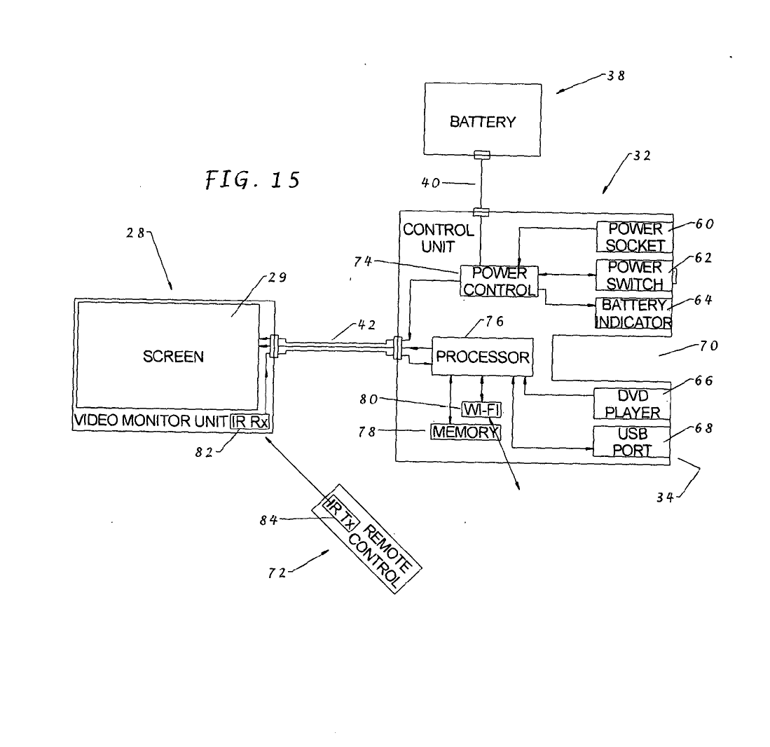

FIG. 15 is a schematic block diagram of the circuitry of the apparatus.

Referring to FIGS. 1 to 14 of the drawings, a display apparatus 10 comprises a display case or picture frame 12 have having top, bottom, right and left frame members 14T,B,L,R. A glass 16 and, behind it, a front opaque panel 18 are fitted into a rabbet or rebate 20 in the frame members 14. The front panel 18 is formed with one or more apertures 22 in any desired position(s) for one or more articles 24 to be displayed (one article 24 being shown as a simple rectangular block in the drawings), and one or more apertures 26 in any desired positions for one or more video monitor units 28 (one being shown in the drawings). A rear opaque panel 30, larger in size than the aperture 22 in the front panel 18, is fitted behind the aperture 22 in the front panel 18, and a rectangular spacer frame 31 is provided between the front and rear opaque panels 18,30 so that a space of significant depth is provided between the glass 16 and the rear opaque panel 30 to accommodate the article 24 to be displayed. The article 24 may be fixed to the rear opaque panel 30. The video monitor unit 28 is fitted behind the aperture 26 so that a screen 29 of the video monitor unit 28 is visible through the aperture 26.

A control unit 32 is fitted behind the front opaque panel 18 towards the right of the picture frame 12 and has a control panel 34 which protrudes into a slot 36 in the right frame member 14R so that the control panel 34 is accessible. One or more rechargeable batteries 38 (two being shown in the drawings) are also fitted behind the front opaque panel 18. The batteries 38 are connected to the control unit 32 by battery cables 40 and the video monitor unit 28 is connected to the control unit 32 by a video cable 42. The batteries 38, cables 40,42 and the control unit 32 (apart from its control panel 34) are hidden from view by the front opaque panel 18.

A tray 44 is fitted into the picture frame 12 behind the components described above. The tray 44 is shaped so that it is a snug fit in the rabbet 20 in the picture frame 12, and so that it is a snug fit around the video monitor unit 28, the rear opaque panel 30 and its spacer frame 24, the control unit 32, the batteries 38, the cables 40,42 and any connecting plugs at the ends of the cables 40,42. Therefore, as shown in FIGS. 11 A-B, the tray 44 has: a front panel 46; a peripheral lip 48 around the front panel 46 (other than in places where one of the components of the apparatus 10 engages a frame member 14); recesses 50 in the front panel 46 for the video monitor unit 28, the rear opaque panel 30 and its spacer frame 24, the control unit 32 and the batteries 38; channels 52 in the front panel 46 for the cables 40,42; and bulges 54 at the ends of the channels 52, where necessary, for the connector plugs.

A backing board 56 is fitted into a further rabbet 58 in die frame members 14 behind die tray 44 and is secured in place by any suitable means such as pins, screws or adhesive tape. The backing board 56 and glass 16 snugly hold the other contents of the picture frame 12 between them. The backing board may be provided with any suitable device 58 to enable die display apparatus 10 to be hung on a wall, for example from a picture hook.

All of the components of the display unit are therefore snugly held in place, but if desired, the control unit 32 may also be fixed to the right frame member 12R, for example by a pair of screws passing through holes in the frame member 12R at the top and bottom of the slot 36 into screw-threaded holes in the control unit 32.

Referring now to FIG. 15, die control panel 34 of the control unit 32 has: a power socket 60 to enable the display apparatus 10 to be connected to a source of electricity, such as a mains adapter; a power switch 62 to enable the apparatus to be switched on and off by a user; a battery life indicator 64; a disc insertion slot for a DVD player 66 which can play a DVD and provide a video signal to a processor 76, and a USB port 68 which allows the transfer of files between a memory 78 for the storage of video and/or picture files and an external device via a USB cable plugged into the USB port 68. The control panel 34 may also be formed with a recess 70 in which a remote controller 72 for the apparatus 10 can be stowed.

The control unit 32 includes a power control unit 74 which can receive power from a mains adapter via the power socket 60 and from the battery(s) 38 via the battery cable(s) 40.

The power control unit 74 also controls recharging of the battery/ies 38, and is responsive to the switch 62 to control the supply of power to the video monitor unit 28 via the video cable 42, to the processor 76 and to other elements of the control unit 32 via power connections (not shown). The battery indicator 64 is connected to the power control unit 74 and is operable to display the number of hours of remaining battery life. The control unit 32 also includes a wi-fI interface 80 which allows the transfer of files between the memory 18 and a wi-fI network.

The video monitor unit 28 provides merely a monitor function and receives a video signal (for example as an RGB, DVI or HDMI signal) on the video cable 42 from the processor 76 in the control unit 28. The video monitor unit 28 preferably does not include any circuitry fix converting a video or picture tile into a video signal. The video monitor unit 28 preferably uses LCD or OLED display technology. As a result, the video monitor unit 28 can be relatively thin in size.

The housing of the video monitor unit 28 may also contain an infra-red receiver 82 which can supply a control signal to the processor 76 via the video cable 42. The remote controller 72 has a number of pushbuttons (not shown) operable by a user and an infra-red transmitter 84 for transmitting corresponding command codes to the infra-red receiver 82 and thence to the processor 76.

Each battery 38 preferably employs lithium-ion polymer technology so that the battery 38 can readily be constructed of the appropriate physical size and is sufficiently thin in size. Each battery 38 may include a number of cells connected in series so as to provide the required output voltage.

In operation of the display apparatus 10, the apparatus can be powered up using the power switch 62. The apparatus 10 can then be toggled between a “standby” state and an “on” state using the remote controller 2. When in the “on” state, video and or picture files can be transferred between the memory 18 and an external network device or network via the USB port 68 and wi-fI interface 80. The remote controller 12 can then be used by pressing appropriate buttons to cause the processor 76 to display on the monitor unit 10 details of files that are available in the memory 78 and/or on a DVD inserted into the DVD player 66, and to select a file and to cause the processor 76 to convert the file into a video signal which is sent to the monitor unit 28 so that a video or picture is displayed on the screen 29. The remote controller 72 and processor 16 may also be provided with options such as compiling a playlist, playing the playlist, pausing, stopping, repeating and shuffling, and changing screen attributes.

The display apparatus 10 may also be provided with an audio facility, in which case one or more loudspeakers may be mounted in the picture frame 12 between the front picture mount board 42 and the backing board 38 and attached to the bottom frame member 14B, which is apertured to allow sound to escape in this case, the control unit 32 may include an audio interface connected between the processor 76 and the loudspeakers so that the loudspeakers play the audio from the file that is being played on the monitor unit 28. The remote controller 72 and processor 76 may be provided with audio options such as volume control and muting.

It will be appreciated, especially from FIGS. 11A-B and 12 that the components of the display apparatus 10 are not symmetrically arranged, and, therefore, care needs to be taken to ensure that the centre of gravity of the whole apparatus 10 lies on the vertical centreline of the frame 12, otherwise the apparatus 10 will not hang straight. This may be done in a number of ways.

For example, the mass of each component of the apparatus 10 may be ascertained in advance. A layout of some of the components of the apparatus 10 may then be prepared, for example all of the components except the battery 38 or one of the batteries 38. The algebraic sum of the product of the mass of each of those components and the distance of its centre of gravity from the centreline of the frame 12 may then be calculated, with distances to the right and left of the centreline being taken to be positive and negative respectively. That sum may then be divided by the mass of the battery 38 to give a required distance for the centre of gravity of the battery 38 from the centreline, with a positive or negative result being taken to mean to the left or the right.

Alternatively, all of the components of the apparatus 10 may be assembled, and the apparatus 10 may then be hung by the device 58 from a picture hook. The position of one or more of the components such as the battery(s) 38 may then be adjusted until the apparatus hangs straight. The components of the apparatus 10 may then be fixed in position.

In the embodiment of the present invention described above, the tray 44 has a complex shape and is preferably manufactured by vacuum-forming a sheet of thermoplastics material such as high impact polystyrene after the sheet has been heated to its forming temperature. The frame 12 and the other components of the display apparatus 10 may, after they have been laid out in their required relative positions on a vacuum table, be used as the mould formers for the vacuum-forming process. Alternatively, the mould for the vacuum-forming process may be constructed from elements resembling the frame 12 and each of the other elements of the apparatus 10, which are laid out in their required relative positions on a vacuum table. In this case, the elements may be provided with appropriate draft angles so that the moulded tray 44 can be readily released from the mould elements.

It will be appreciated that many modifications and developments may be made to the embodiment of the present invention described above.

For example, although the display unit 10 has been shown in the drawings with the article 24 to be displayed and the screen 29 of the video monitor unit centrally disposed in the frame 12, either or both may be offset from the vertical centre line.

Although one article 24 to be displayed, one video monitor unit 28 and one or two batteries 38 have been described above, other numbers of these items may be provided.

In the case where the article 24 to be displayed is in sheet form (for example a photograph or certificate) the rear opaque panel 30, its spacer frame 31 and the aperture 22 in the front opaque panel 18 may be omitted, and the article 24 may then be sandwiched between the opaque panel 18 and the glass 16.

Not all of the items in the picture frame need be held by the tray 44. For example, the battery(s) 38 may be mounted between the bottom frame member 14B and a parallel rail member and/or between the top frame member 14T and a parallel rail member so that the battery can be slid between laterally of the frame 12 between the frame member 12T,B and the rail member to achieve a required balance of the display unit 10, the battery 38 then being secured in place, for example using sticky tape, and the backing board 56 being fitted.

It should be noted that the embodiment of the present invention has been described above purely by way of example and that many other modifications and developments may be made thereto within the scope of the present invention.

Further according to the present invention there is provided a display apparatus having a portion for displaying an article of memorabilia or the like, said display apparatus having at least one powered image display or the like capable of being theme related to the article of memorabilia or the like, the at least one powered image display being operatively connected, in use, with at least one power source and/or with at least one control unit, said at least one powered image display being separately mounted or mountable in the case or frame from said at least one power source and/or from said at least one control unit, the arrangement being such that the display apparatus is or can be balanced in a selected manner about the centre of gravity to be able to hang the apparatus in a selected orientation from a point location.

It is possible that more than one powered image display is provided or the image display may be replaced by an audio display only.

It is to be understood that the scope of the present invention is not to be unduly limited by the particular choice of terminology and that a specific term may be replaced or supplemented by an equivalent or generic term. For example, the term ‘space’ or ‘opening’ could be replaced by ‘cavity’, ‘recess’ or ‘aperture’ or the like; ‘display case’ could be replaced by ‘display box’; ‘battery unit’ may be replaced by ‘power unit’ or ‘power supply’; ‘panel’ could be replaced by ‘member’ or ‘bracket’ or ‘tray’. Further it is to be understood that individual features, method or functions relating to the display apparatus, or combinations thereof might be individually patentably inventive. The singular may include the plural and vice versa. Words used to convey position or direction such as ‘left’ or ‘right’ should not be construed as limiting and are given to provide an indication of possible relative orientations, in use. Additionally, any range mentioned herein for any parameter or variable shall be taken to include a disclosure of any derivable sub-range within that range or of any particular value of the variable or parameter arranged within, or at an end of, the range or sub-range.

1. A display apparatus (10) comprising:—a display case or picture frame (12) having or containing:
an opening or space for an article (24) to be displayed, an electronic or powered image display unit (28), and at least one of:—
a) at least one control unit (32) for controlling the image display unit, and
b) at least one power source or battery unit (38) for powering the image display unit;
and wherein:
the image display unit is separately mounted in the display case/picture frame from the control unit(s) and/or power source/battery unit(s) and is connected thereto by at least one operative connection or cable (40,42).

2. The display apparatus as claimed in claim 1, wherein:
the display case or picture frame has or contains such a control unit (32).

3. The display apparatus as claimed in claim 2, wherein:
the display case or picture frame includes framing members (14T,H,R,L) at edges of the case/picture frame; and
the control unit is disposed adjacent one of the framing members (14R) and is accessible through an aperture (36) in or through that framing member and, preferably, wherein said
one framing member is disposed on the right or the left of the picture frame/display case, in use, and/or wherein the control unit includes means (66,68,78,80) for receiving and/or storing a video or picture file and/or video stream and for generating a video monitor signal therefrom; and the image display unit is a monitor (28) connected to receive the video monitor signal from said control unit and operable to display a still and/or moving picture represented by the video monitor signal.

4. The display apparatus as claimed in claim 1, wherein:
the display case/picture frame has or contains at least one such power source/battery unit (38).

5. The display apparatus as claimed in claim 4, which
includes means for mounting said one battery unit/power source in a range of lateral positions across the display case/picture frame and for securing said one battery unit/power source in a selected one of those positions.

6. The display apparatus as claimed in claim 4, wherein:
the display case or picture frame contains a plurality of such battery units/power sources (38).

7. The display apparatus as claimed in claim 1, wherein:
the display case or picture frame has or contains a transparent front panel (16) covering the opening or space for the article to be displayed, the image display unit and the control unit(s) and/or power source/battery unit(s).

8. The display apparatus as claimed in claim 1, wherein:
the display case or picture frame contains an opaque panel (18) which covers the control unit(s) and/or power source/battery unit(s) and which has an aperture (26) revealing the image display unit(s).

9. The display apparatus as claimed in claim 8, wherein:
the opening or space for the article to be displayed is provided between the transparent panel and the opaque panel and, preferably, wherein the frame/case contains a second opaque panel (30) mounted behind a second aperture (22) in the first-mentioned opaque panel; and the opening or space for the article to be displayed is provided in and/or behind the second aperture in the first opaque panel and in front of the second opaque panel.

10. The display apparatus as claimed in claim 1, wherein:
a panel (44) is disposed within the frame behind the image display unit and the control unit(s) and/or power source/battery unit(s) and is shaped to engage the frame, the image display unit and the control unit(s) and/or power source/battery unit(s) so as to maintain their relative positions.

11. The display apparatus as claimed in claim 1, further including;
means (58) to enable the picture frame/display apparatus to be hung from a picture hook or the like on a wall.

12. A method of making a display apparatus comprising the steps of:—
selecting a picture frame or display case and an image display unit; selecting at least one of; at least one control unit for controlling the image display unit and at least one power source or battery unit; choosing a position for the image display unit, mounting the image display unit in the picture frame/display case separately to the at least one control unit and/or power source/battery unit(s) and operatively connecting the image display unit to the control unit(s) and/or power source or battery unit(s) and, preferably, choosing and/or calculating positions for the or each control unit/power source or battery unit in the picture frame/display case, so that, when in these positions, the overall centre of gravity of the display apparatus lies substantially on a vertical centerline of the picture frame/display apparatus or at a pre-selected location, and assembling the display apparatus in accordance with the chosen/calculated positions of the or each control unit/power source or battery unit.

13. The method as claimed in claim 12 comprising the step of vacuum-forming a sheet of plastics material to fit the image display unit, the or each control unit and the or each battery unit in the chosen/calculated positions in the picture frame/display case, and, preferably, the sheet of plastics material is vacuum-formed using the picture frame/display case, image display unit, the or each control unit and the or each power source/battery unit as farmers in the vacuum-forming process.

14. The method as claimed in claim 12 comprising adjusting the position (preferably lateral position) of the or each one power source/battery unit so that the overall centre of gravity of the display apparatus lies substantially on a vertical centreline of the picture frame/case or at a pre-selected location; and securing said one power source/battery unit in the adjusted position.

15. A display apparatus (10) having a portion for displaying an article of memorabilia or the like, said display apparatus (10) having at least one powered image display (28) or the like capable of being theme related to the article of memorabilia or the like, the at least one powered image display (28) being operatively connected, in use, with at least one power source (38) and/or with at least one control unit (32), said at least one powered image display (28) being separately
mounted or mountable in the case or frame (12) from said at least one power source (38) and/or from said at least one control unit (32), the arrangement, preferably, being such that the display apparatus (10) is or can be balanced in a selected manner about the centre of gravity to be able to hang the apparatus from a point location in a selected orientation.
